(19) United States
(12) Patent Application Publication
(10) Pub. No.: US 2025/0125881 A1
(43) Pub. Date: Apr. 17, 2025

(54) OPTICAL TRANSMISSION MODULE

(71) Applicant: QuantumZ Inc., KAOHSIUNG CITY (TW)

(72) Inventors: CHUN-CHIEH CHEN, KAOHSIUNG CITY (TW); MING-CHE HSIEH, KAOHSIUNG CITY (TW); PO-TING CHEN, KAOHSIUNG CITY (TW); HUNG-CHUN KENG, KAOHSIUNG CITY (TW)

(21) Appl. No.: 18/899,557

(22) Filed: Sep. 27, 2024

(30) Foreign Application Priority Data
Oct. 12, 2023 (TW) 112138962

(51) Int. Cl. H04B 10/69; G02B 6/42; H03F 3/08; H04B 10/40

(52) U.S. Cl. CPC H04B 10/693; G02B 6/4207; G02B 6/4246; H03F 3/08; H04B 10/40

(57) ABSTRACT

An optical transmission module is provided, including: a substrate, a transmitting side and a receiving side. The substrate defines a thickness direction and includes a optical transmission channel and two refractive portions located at two opposite sides of the optical transmission channel, and each of the two refractive portions is provided with a progressive refractive index progressively increased or decreased in the thickness direction. The transmitting side includes an optical transmitter and a driver, and the optical transmitter is electrically connected with the driver by wire bonding. The receiving side includes an optical receiver and a transimpedance amplifier, and the optical receiver is electrically connected with the transimpedance amplifier by wire bonding. At least one of the optical transmitter and the optical receiver includes a light transmission face and a conductive surface, and each said light transmission face faces toward one of the two refractive portions.

### BACKGROUND OF THE INVENTION

### Field of the Invention

The present invention relates to an optical transmission module for guiding a transmission signal.

### Description of the Prior Art

In conventional optical transmission technology, I/O pads and a light emitting surface of an optical transmitter (or a light receiving surface of an optical receiver) are arranged at the same side of the optical transmitter. The light emitting surface faces an optical waveguide, and the I/O pads are electrically connected with a circuit board. Due to manufacturing tolerances, the light emitting surface or the light receiving surface cannot be aligned with the optical waveguide accurately, and this results in poor optical coupling efficiency and signal loss.

In a conventional optical transmission device, there is usually an air gap between the optical waveguide board and the optical transmitter or the optical receiver, which makes the divergence angle of the light projecting from the optical transmitter toward the optical waveguide board or the divergence angle of the light projecting from the optical waveguide board toward the optical receiver large, and this results in high loss and low optical coupling efficiency. In addition, wires connected between the optical transmitter and a driver are intersected with each other so that the signals transmitted therethrough are easy to interfere with each other, which also results in poor transmission effect.

The present invention is, therefore, arisen to obviate or at least mitigate the above-mentioned disadvantages.

### SUMMARY OF THE INVENTION

The main object of the present invention is to provide an optical transmission module, which achieves low loss and good signal transmission effect.

To achieve the above and other objects, the present invention provides an optical transmission module, including: a substrate, a transmitting side and a receiving side. The substrate defines a thickness direction and includes a optical transmission channel and two refractive portions located at two opposite sides of the optical transmission channel. The optical transmission channel includes two first reflective surfaces respectively inclined to the thickness direction, and each of the two first reflective surfaces corresponds to one of the two refractive portions. Each of the two refractive portions is provided with a progressive refractive index which is progressively increased or progressively decreased in the thickness direction. The transmitting side includes an optical transmitter and a driver disposed on the substrate, and the optical transmitter is electrically connected with the driver by wire bonding. The receiving side includes an optical receiver and a transimpedance amplifier disposed on the substrate, and the optical receiver is electrically connected with the transimpedance amplifier by wire bonding. At least one of the optical transmitter and the optical receiver includes a light transmission face and a conductive surface opposite to each other, and each said light transmission faces toward one of the two refractive portions.

To achieve the above and other objects, the present invention further provides an optical transmission module, including: a substrate, a transmitting side, a receiving side and at least one light guide mechanism. The substrate defines a thickness direction and includes a optical transmission channel and two refractive portions located at two opposite sides of the optical transmission channel. The optical transmission channel includes two first reflective surfaces respectively inclined to the thickness direction, and each of the two first reflective surfaces corresponds to one of the two refractive portions. Each of the two refractive portions is provided with a progressive refractive index which is progressively increased or progressively decreased in the thickness direction. The transmitting side includes an optical transmitter and a driver disposed on the substrate, and the optical transmitter is electrically connected with the driver by wire bonding. The receiving side includes an optical receiver and a transimpedance amplifier disposed on the substrate, and the optical receiver is electrically connected with the transimpedance amplifier by wire bonding. At least one of the optical transmitter and the optical receiver is misaligned with the two refractive portions in the thickness direction, and each said light guide mechanism is connected between one of the two refractive portions and one of the optical transmitter and the optical receiver.

The present invention will become more obvious from the following description when taken in connection with the accompanying drawings, which show, for purpose of illustrations only, the preferred embodiment(s) in accordance with the present invention.

### BRIEF DESCRIPTION OF THE DRAWINGS

FIG. 1 is a cross-sectional view of a first preferable embodiment of the present invention;

FIG. 2 is a partial enlargement of FIG. 1;

FIG. 3 is a top view showing connection of an optical transmitter and a driver according to the first preferable embodiment of the present invention;

FIG. 4 is a cross-sectional view of a second preferable embodiment of the present invention;

FIG. 5 is a partial enlargement of FIG. 4;

FIG. 6 is a top view showing connection of an optical transmitter, a driver and a light guide mechanism according to the second preferable embodiment of the present invention;

FIG. 7 is a cross-sectional view of a third preferable embodiment of the present invention; and

FIG. 8 is a partial enlargement of FIG. 7.

### DETAILED DESCRIPTION OF THE PREFERRED EMBODIMENTS

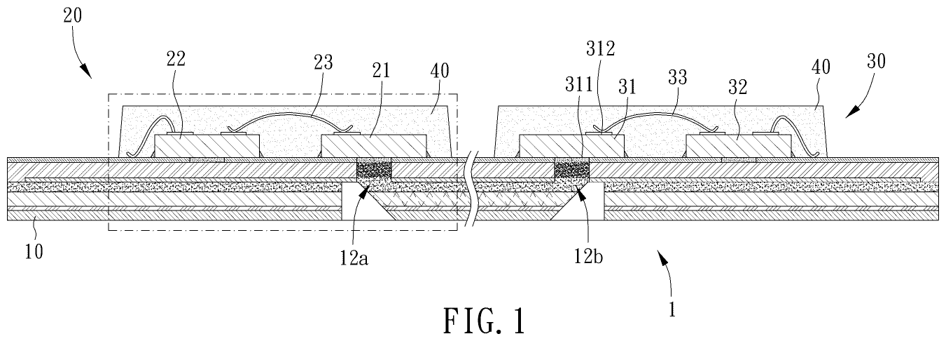

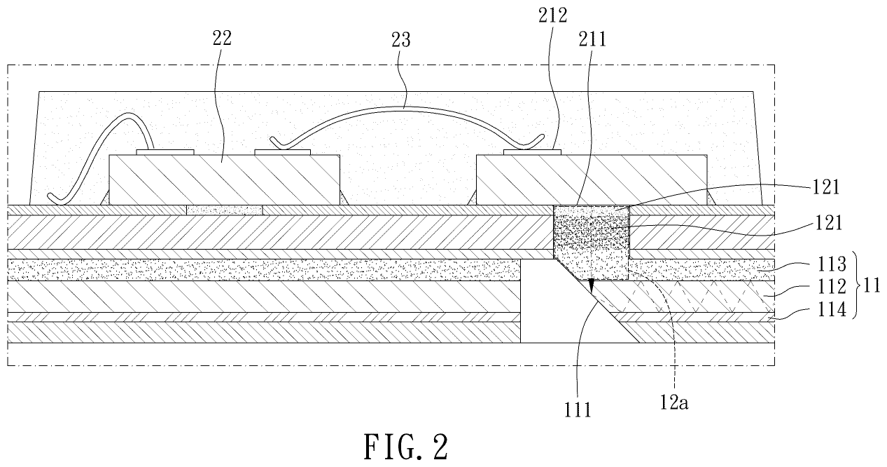

Please refer to FIGS. 1 to 3 for a first preferable embodiment of the present invention. An optical transmission module 1 of the present invention includes a substrate 10, a transmitting side 20 and a receiving side 30.

The substrate 10 defines a thickness direction and includes a optical transmission channel 11 and two refractive portions 12a, 12b located at two opposite sides of the optical transmission channel 11. The optical transmission channel 11 includes two first reflective surfaces 111 respectively inclined to the thickness direction, and each of the two first reflective surfaces 111 corresponds to one of the two refractive portions 12a, 12b. Each of the two refractive portions 12a, 12b is provided with a progressive refractive index which is progressively increased or progressively decreased in the thickness direction. The transmitting side 20 includes an optical transmitter 21 (such as vertical cavity surface emitting laser (VCSEL) or LED) and a driver 22 disposed on the substrate 10, and the optical transmitter 21 is electrically connected with the driver 22 by wire bonding. The receiving side 30 includes an optical receiver 31 (such as a photodiode (PD)) and a transimpedance amplifier 32 (TIA) disposed on the substrate 10, and the optical receiver 31 is electrically connected with the transimpedance amplifier 32 by wire bonding. Therefore, the two refractive portions 12a, 12b effectively guide and narrow a transmission signal from the optical transmitter 21 or from one of the two first reflective surfaces 111 toward the optical receiver 31 which converges and densifies the transmission signal and effectively improves optical coupling efficiency. By wire bonding, a transmission distance and noise interference between the optical transmitter 21 and the driver 22 and/or between the optical receiver 31 and the transimpedance amplifier 32 can be reduced, which provides good signal transmission effect.

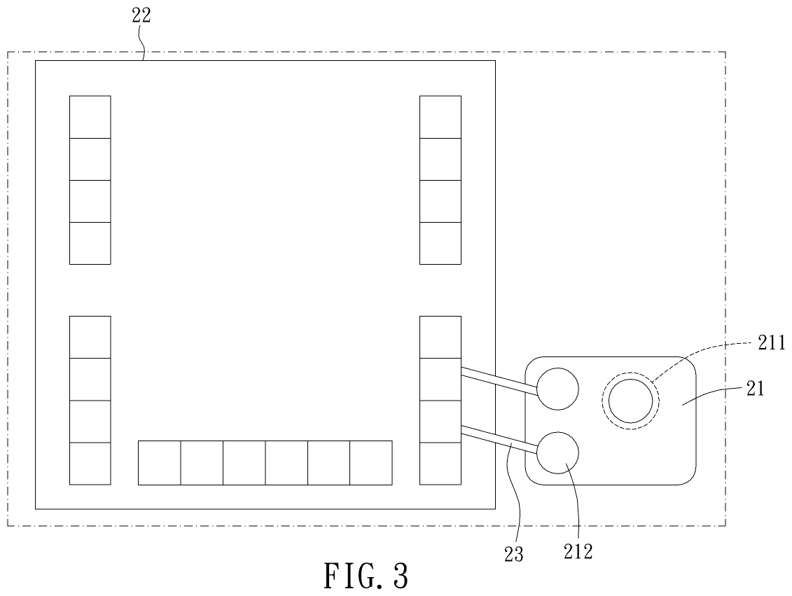

In this embodiment, at least one of the optical transmitter 21 and the optical receiver 31 includes a light transmission face 211, 311 and a conductive surface 212, 312 opposite to each other, and each said light transmission face 211, 311 faces toward one of the two refractive portions 12a, 12b, which allows for accurate coupling and facilitates wire bonding. Please refer to FIG. 3, at least one of the transmitting side 20 and the receiving side 30 further includes two wires 23, 33, and the two wires 23, 33 are preferably non-intersected with each other and connected between one said conductive surface 212, 312 and one of the driver 22 and the transimpedance amplifier 32, which reduces mutual interference of electrical signals transmitted through the two wires 23, 33 and improves optical transmission efficiency. In other embodiments, the two wires may be intersected with each other to meet different requirements.

Preferably, the optical transmission module 1 further includes at least one first covering component 40 disposed on the substrate 10, and each said first covering component 40 covers and integrally connects the optical transmitter 21 and the driver 22, or the optical receiver 31 and the transimpedance amplifier 32 so as to avoid displacement of components. The at least one first covering component 40 preferably integrally covers the two wires 23, 33 so as to have good structural stability. The at least one first covering component 40 may be a molding compound and is provided with electromagnetic wave shielding and a thermal conductivity greater than 3 W/mK, which can lower the electromagnetic wave interference and improves heat dissipation. In other embodiments, said first covering components may respectively cover the optical transmitter, the driver, the optical receiver and the transimpedance amplifier so that the optical transmission module maintains good flexibility.

Each of the two refractive portions 12a, 12b includes a plurality of refractive layers 121 arranged in the thickness direction, and the plurality of refractive layers 121 have different refractive index and may be integrally formed or formed layer by layer. The refractive index and thickness of the plurality of refractive layers 121 are designable to meet different light guiding requirements. Specifically, the optical transmission channel 11 includes a transmission layer 112 and a first layer 113 (cladding) arranged at a side of the transmission layer 112, and the two refractive portions 12a, 12b are integrally connected with the first layer 113 and exposed on a side of the substrate 10, which facilitates the light transmission faces 211, 311 of the optical transmitter 21 and the optical receiver 31 to be aligned thereto. The two first reflective surfaces 111 are configured to reflect the transmission signal and extends respectively from a side of the substrate 10 remote from one of the two refractive portions 12a, 12b to the first layer 113. Therefore, the transmission signal can be transmitted from the optical transmitter 21 toward the transmission layer 112 or from the transmission layer 112 toward the optical receiver 31. The optical transmission channel 11 further includes a second layer 114 opposite to the first layer 113. Each of the first layer 113 and the second layer 114 may be in gaseous, liquid or solid state, such as air, water or metal, or any substance with a refractive index smaller than a refractive index of the transmission layer 112, and the transmission signal can be transmitted in total reflection in the optical transmission channel 11.

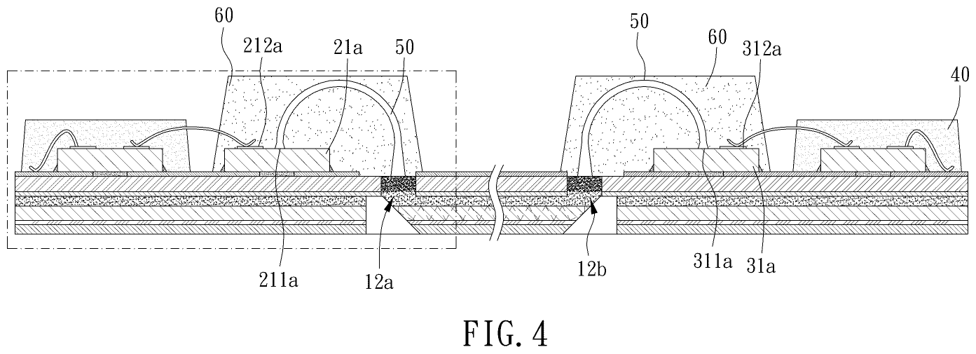

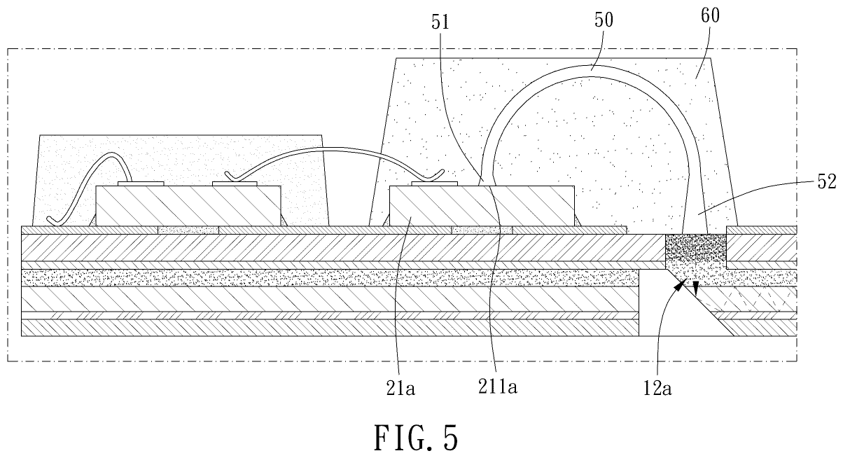

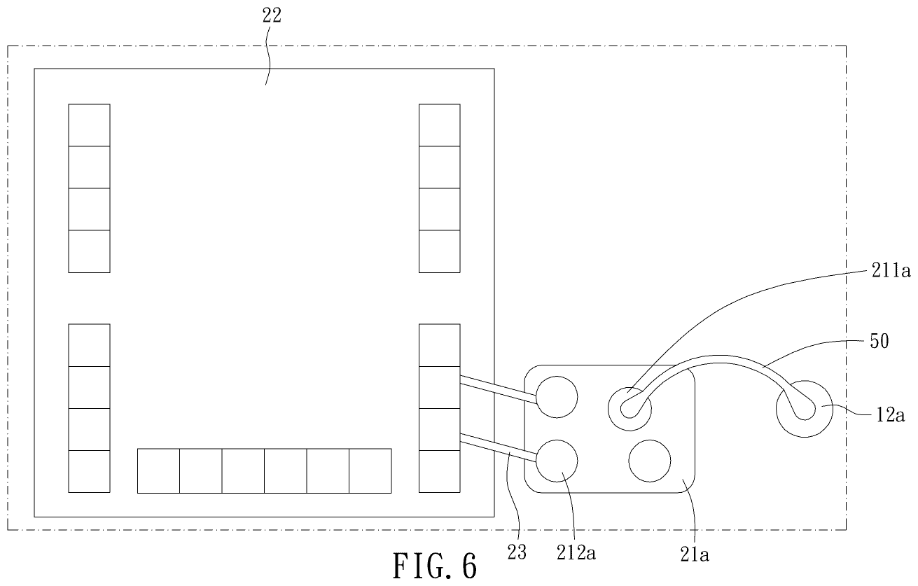

Please refer to a second preferable embodiment shown in FIGS. 4 to 6, which is different from the first preferable embodiment in that: the optical transmission module 1a further includes at least one light guide mechanism 50. At least one of the optical transmitter 21a and the optical receiver 31a is misaligned with the two refractive portions 12a, 12b in the thickness direction, and each said light guide mechanism 50 is connected between one of the two refractive portions 12a, 12b and one of the optical transmitter 21a and the optical receiver 31a. Therefore, each said light transmission face 211a, 311a and one of the two refractive portions 12a, 12b are coupled with each other by one said light guide mechanism 50, which is accurate and easy to be processed.

Furthermore, a side of at least one of the optical transmitter 21a and the optical receiver 31a remote from the substrate 10 has the light transmission face 211a, 311a and the conductive surface 212a, 312a, and each said light transmission face 211a, 311a is misaligned with one of the two refractive portions 12a, 12b in the thickness direction. Thus, a distance between the optical transmitter 21a and the driver 22 or a distance between the optical receiver 31a and the transimpedance amplifier 32 are greatly shortened, and lengths of the wires 23, 33 are shortened, which also improves optoelectronic transmission efficiency.

In this embodiment, each said light guide mechanism 50 is a polymer wire being flexible. One end of the polymer wire is connected with the light transmission face 211a, 311a of one of the optical transmitter 21a and the optical receiver 31a, and the other end of the polymer wire is connected with an end surface of one of the two refractive portions 12a, 12b remote from the optical transmission channel 11. Each said light guide mechanism 50 includes a light-input end portion 51 and a light-output end portion 52, and at least one of the light-input end portion 51 and the light-output end portion 52 is provided with a progressive refractive index which is progressively increased or progressively decreased in a light guiding direction of said light guide mechanism 50 so as to effectively guide the transmission signal and avoid optical loss. Preferably, a diametrical dimension of the light-input end portion 51 and a diametrical dimension of the light-output end portion 52 are respectively smaller than or equal to a diametrical dimension of one of the two refractive portions 12a, 12b, and the diametrical dimension of the light-input end portion 51 and the diametrical dimension of the light-output end portion 52 are respectively increased gradually in a direction toward one of the two refractive portions 12a, 12b, which provides light guiding effect, easier coupling and lower loss. In other embodiments, each of the light-input end portion and the light-output end portion may have a single diametrical dimension; each of the light-input end portion and the light-output end portion may have a single refractive index.

Preferably, the optical transmission module 1a further includes at least one second covering component 60 disposed on the substrate 10, and each said second covering component 60 covers and integrally connects one said light guide mechanism 50 and one of the optical transmitter 21a and the optical receiver 31a for stable assembly. Moreover, the at least one first covering component 40 only covers the driver 22 (or the transimpedance amplifier 32) and a portion of the two wires 23, 33 and is spaced apart from the at least one second covering component 60 so that the optical transmission module 1 has preferable flexibility. The at least one first covering component 40 and the at least one second covering component 60 may be made of different materials. Specifically, the at least one second covering component 60 may be made of a material having a low refractive index which is lower than a refractive index of the at least one light guide mechanism 50. Preferably, the low refractive index may be between 1.45 and 1.6, which is selectable according to a material of the at least one light guide mechanism 50. Each said second covering component 60 preferably completely covers one said light transmission face 211a, 311a and the end surface of one of the two refractive portions 12a, 12b so as to reduce optical loss. In other embodiments, the at least one first covering component and the at least one second covering component may be made of the same material; the at least one first covering component and the at least one second covering component may be integrally formed; the optical transmitter, the driver and the light guide mechanism may be integrally covered by one said first covering component or one said second covering component; the optical receiver, the transimpedance amplifier and the light guide mechanism may be integrally covered by one said first covering component or one said second covering component.

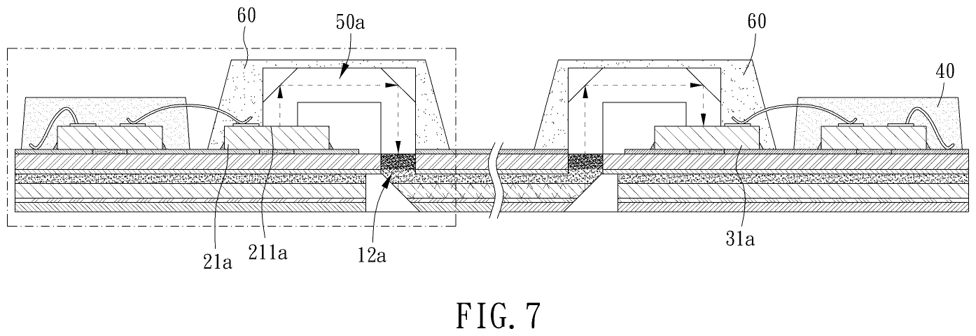

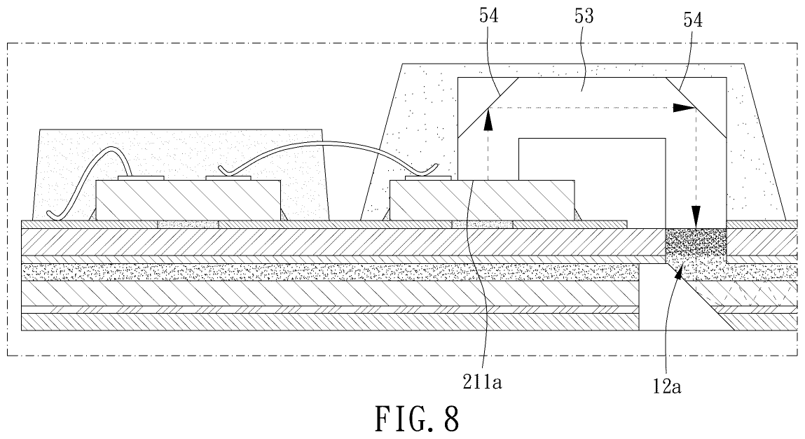

Please refer to a third preferable embodiment shown in FIGS. 7 and 8, which is different from the second preferable embodiment in that: each said light guide mechanism 50a includes at least one light guide body 53 and at least one second reflective surface 54 disposed on the at least one light guide body 53. One said second reflective surface 54 of each said light guide mechanism 50a corresponds to one of the two the refractive portions 12a, 12b and one of the two first reflective surfaces 111 in the thickness direction. The at least one light guide body 53 may be an optical lens formed as one piece and include two said second reflective surfaces 54, and one of the two said second reflective surfaces 54 faces toward the light transmission face 211a, 311a of the optical transmitter 21a or the optical receiver 31a, and the other of the two said second reflective surfaces 54 faces toward one of the two refractive portions 12a, 12b so as to guide the transmission signal to turn and transmit, and have good structure strength and assembling stability. In other embodiments, the at least one light guide body may include a plurality of optical lens connected with one another, and a number of said second reflective surfaces may be more than two according to an optical path of the at least one light guide mechanism. Each said light guide body may be made of other light-guiding materials which allows light transmission between one said light transmission face and one of the two refractive portions.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. An optical transmission module, including:
a substrate, defining a thickness direction, including a optical transmission channel and two refractive portions located at two opposite sides of the optical transmission channel, the optical transmission channel including two first reflective surfaces respectively inclined to the thickness direction, each of the two first reflective surfaces corresponding to one of the two refractive portions, each of the two refractive portions provided with a progressive refractive index which is progressively increased or progressively decreased in the thickness direction;
a transmitting side, including an optical transmitter and a driver disposed on the substrate, the optical transmitter electrically connected with the driver by wire bonding; and
a receiving side, including an optical receiver and a transimpedance amplifier disposed on the substrate, the optical receiver electrically connected with the transimpedance amplifier by wire bonding;
wherein at least one of the optical transmitter and the optical receiver includes a light transmission face and a conductive surface opposite to each other, and each said light transmission faces toward one of the two refractive portions.

2. The optical transmission module of claim 1, wherein at least one of the transmitting side and the receiving side further includes two wires, and the two wires are non-intersected with each other and connected between one said conductive surface and one of the driver and the transimpedance amplifier.

3. The optical transmission module of claim 1, further including at least one first covering component disposed on the substrate, wherein each said first covering component covers and integrally connects the optical transmitter and the driver, or the optical receiver and the transimpedance amplifier.

4. The optical transmission module of claim 1, wherein the optical transmission channel includes a transmission layer and a first layer arranged at a side of the transmission layer, and the two refractive portions are integrally connected with the first layer and exposed on a side of the substrate.

5. An optical transmission module, including:
a substrate, defining a thickness direction, including a optical transmission channel and two refractive portions located at two opposite sides of the optical transmission channel, the optical transmission channel including two first reflective surfaces respectively inclined to the thickness direction, each of the two first reflective surfaces corresponding to one of the two refractive portions, each of the two refractive portions provided with a progressive refractive index which is progressively increased or progressively decreased in the thickness direction;
a transmitting side, including an optical transmitter and a driver disposed on the substrate, the optical transmitter electrically connected with the driver by wire bonding;
a receiving side, including an optical receiver and a transimpedance amplifier disposed on the substrate, the optical receiver electrically connected with the transimpedance amplifier by wire bonding; and
at least one light guide mechanism, at least one of the optical transmitter and the optical receiver misaligned with the two refractive portions in the thickness direction, each said light guide mechanism connected between one of the two refractive portions and one of the optical transmitter and the optical receiver.

6. The optical transmission module of claim 5, wherein a side of at least one of the optical transmitter and the optical receiver remote from the substrate has a light transmission face and a conductive surface, each said light transmission face is misaligned with one of the two refractive portions in the thickness direction.

7. The optical transmission module of claim 6, wherein at least one of the transmitting side and the receiving side further includes two wires, and the two wires are non-interleaved with each other and connected between one said conductive surface and one of the driver and the transimpedance amplifier.

8. The optical transmission module of claim 5, further including at least one first covering component disposed on the substrate, wherein each said first covering component covers and integrally connects the optical transmitter and the driver, or the optical receiver and the transimpedance amplifier.

9. The optical transmission module of claim 5, wherein the optical transmission channel includes a transmission layer and a first layer arranged at a side of the transmission layer, and the two refractive portions are integrally connected with the first layer and exposed on a side of the substrate.

10. The optical transmission module of claim 5, wherein each said light guide mechanism is a polymer wire being flexible, one end of the polymer wire is connected with a light transmission face of one of the optical transmitter and the optical receiver, and the other end of the polymer wire is connected with an end surface of one of the two refractive portions remote from the optical transmission channel.

11. The optical transmission module of claim 5, wherein each said light guide mechanism includes at least one light guide body and at least one second reflective surface disposed on the at least one light guide body, and one said second reflective surface of each said light guide mechanism corresponds to one of the two refractive portions and one of the two first reflective surfaces in the thickness direction.

12. The optical transmission module of claim 5, further including at least one second covering component disposed on the substrate, wherein each said second covering component covers and integrally connects one said light guide mechanism and one of the optical transmitter and the optical receiver.

13. The optical transmission module of claim 5, wherein each said light guide mechanism includes a light-input end portion and a light-output end portion, at least one of the light-input end portion and the light-output end portion is provided with a progressive refractive index which is progressively increased or progressively decreased in a light guiding direction of said light guide mechanism.

14. The optical transmission module of claim 5, wherein each said light guide mechanism includes a light-input end portion and a light-output end portion, a diametrical dimension of the light-input end portion and a diametrical dimension of the light-output end portion are respectively smaller than or equal to a diametrical dimension of one of the two refractive portions.
